(19) United States
(12) Patent Application Publication
(10) Pub. No.: US 2023/0290693 A1
(43) Pub. Date: Sep. 14, 2023

(54) SEMICONDUCTOR MANUFACTURING DEVICE AND METHOD FOR MANUFACTURING SEMICONDUCTOR DEVICE

(71) Applicant: KIOXIA CORPORATION, Tokyo (JP)

(72) Inventor: Junji TOKUNAGA, Yokkaichi Mie (JP)

(73) Assignee: KIOXIA CORPORATION, Tokyo (JP)

(21) Appl. No.: 17/901,667

(22) Filed: Sep. 1, 2022

(30) Foreign Application Priority Data
Mar. 10, 2022 (JP) 2022-037410

(51) Int. Cl. H01L 21/66; H01L 21/02; H01L 21/67

(52) U.S. Cl. CPC H01L 22/26; H01L 21/02282; H01L 21/67259

(57) ABSTRACT

According to one embodiment, a semiconductor manufacturing device includes a holder, a discharger, a driver, a controller, first and second sensors, and a processor. The holder holds a substrate and rotates. The discharger discharges a liquid to a front surface of the substrate held by the holder. The driver displaces the discharger. The controller controls the driver such that the liquid is discharged to a discharge position of the front surface. The first sensor measures a first distance from a reference surface below a rear surface of the substrate to a first position of the rear surface. The second sensor measures a second distance from the reference surface to a second position of the rear surface, the second point being on an inner side from the first position of the rear surface. The processor corrects the discharge position based on the first distance and the second distance

### CROSS-REFERENCE TO RELATED APPLICATION(S)

This application is based upon and claims the benefit of priority from Japanese Patent Application No. 2022-037410, filed Mar. 10, 2022, the entire contents of which are incorporated herein by reference.

### FIELD

Embodiments described herein relate generally to a semiconductor manufacturing device and a method for manufacturing a semiconductor device.

### BACKGROUND

In a process for manufacturing a semiconductor device or the like, a spin coat method for discharging a liquid to a front surface of a substrate and rotating the substrate to coat the front surface of the substrate with the liquid is used. When such a spin coat method is performed, if the substrate is warped, the liquid discharged to the substrate flows in an unintended direction due to the inclination of the substrate, and thus a highly precise process becomes difficult.

### DESCRIPTION OF THE DRAWINGS

FIG. 1 is a side view illustrating an example of a configuration of a semiconductor manufacturing device according to an embodiment.

FIG. 2 is a bottom view of a substrate illustrating examples of a first position and a second position according to an embodiment.

FIG. 3 is a top view of the substrate illustrating an example of a process area according to an embodiment.

FIG. 4 is a side view of an example of a state in a film forming process according to an embodiment.

FIG. 5 is a side view of an example of a state in a peeling process according to an embodiment.

FIG. 6 is a block diagram illustrating an example of a functional configuration of a control device according to an embodiment.

FIG. 7 is a side view illustrating an example of a state when the substrate is warped in a convex shape in an embodiment.

FIG. 8 is a side view illustrating an example of a state when the substrate is warped in a concave shape in an embodiment.

FIG. 9 is a diagram illustrating an example of a correction table according to an embodiment.

FIG. 10 is a flowchart illustrating an example of a process when a driving device is controlled in the semiconductor manufacturing device according to an embodiment.

FIG. 11 is a flowchart illustrating an example of a process of a method for manufacturing a semiconductor device using the semiconductor manufacturing device according to an embodiment.

### DETAILED DESCRIPTION

Embodiments provide a semiconductor manufacturing device and a method for manufacturing a semiconductor device in which a process by a spin coat method can be highly precisely performed even when a substrate is warped.

In general, according to one embodiment, a semiconductor manufacturing device is provided. The semiconductor manufacturing device includes a holding unit or holder, a discharge unit or discharger, a driving unit or driver, a controller, a first sensor, a second sensor, and a correction unit. The holding unit holds a substrate and rotates. The discharge unit discharges a liquid to a front surface of the substrate held by the holding unit. The driving unit displaces the discharge unit. The controller controls the driving unit so that the liquid is discharged to a predetermined discharge position of the front surface. The first sensor measures a first distance from a reference surface below a rear surface of the substrate held by the holding unit to a first position of the rear surface. The second sensor measures a second distance from the reference surface to a second position of the rear surface, the second position being on an inner side from the first position of the rear surface. The correction unit corrects the discharge position based on the first distance and the second distance.

Hereinafter a semiconductor manufacturing device and a method for manufacturing a semiconductor device according to the embodiment are described with reference to the accompanying drawings. In addition, the present disclosure is not limited to the following embodiments. In addition, elements in the following embodiments include those that can be easily conceived by those skilled in the art or those that are substantially the same.

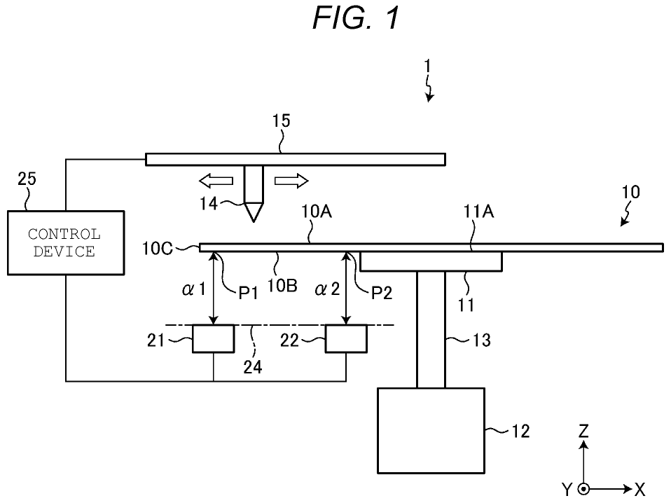

FIG. 1 is a side view illustrating an example of a configuration of a semiconductor manufacturing device 1 according to the embodiment. In the drawings, an X axis corresponds to a left-right direction of a paper surface, a Y axis corresponds to a front-back direction of the paper surface, and a Z axis corresponds to an up-down direction of the paper surface. The semiconductor manufacturing device 1 according to the present embodiment is a device having a function of coating a front surface 10A of a substrate 10 with a predetermined liquid by a spin coat method.

The semiconductor manufacturing device 1 according to the present embodiment includes a spin chuck 11 (an example of the holding unit or holder), a motor 12, a shaft 13, a discharge nozzle 14 (an example of the discharge unit or discharger), a driving device 15 (an example of the driving unit or driver), a first sensor 21, a second sensor 22, and a control device 25.

The spin chuck 11 holds the substrate 10 and rotates by receiving the power of the motor 12. A holding surface 11A that holds a rear surface 10B of the substrate 10 by a predetermined mechanism (e.g., a suction mechanism) is provided on an upper surface of the spin chuck 11. The shaft 13 that transmits the power of the motor 12 is fixed to a lower surface of the spin chuck 11. The substrate 10 that is held on the holding surface 11A of the spin chuck 11 can be rotated by the driving of the motor 12.

The discharge nozzle 14 discharges the predetermined liquid to the front surface 10A of the substrate 10 that is held by the spin chuck 11. The liquid is appropriately selected according to a type of a process with respect to the front surface 10A of the substrate 10, and may be a liquid including a resist, a thinner, or the like.

The driving device 15 is a device that displaces the discharge nozzle 14, and may be implemented by an actuator, a motor, a link mechanism, a control circuit, or the like. The driving device 15 according to the present embodiment can displace the discharge nozzle 14 at least in a radial direction of the substrate 10 (a direction parallel to the X axis). In addition, the driving device 15 may displace the discharge nozzle 14 in a direction other than the corresponding radial direction, for example, in a direction parallel to the Y axis or a direction parallel to the Z axis.

The first sensor 21 and the second sensor 22 are distance measuring sensors provided below the rear surface 10B of the substrate 10 held by the spin chuck 11. The first sensor 21 measures a first distance α1 from a reference surface 24 below the rear surface 10B of the substrate 10 to a first position P1 of the rear surface 10B of the substrate 10. The second sensor 22 measures a second distance α2 from the reference surface 24 to a second position P2 of the rear surface 10B of the substrate 10, the second position P2 being on an inner side from the first position P1 of the rear surface 10B of the substrate 10. The reference surface 24 is, for example, installation positions of the first sensor 21 and the second sensor 22. Specific configurations of the first sensor 21 and the second sensor 22 are not particularly limited, but the first sensor 21 and the second sensor 22 may be sensors that measure distances, for example, based on time of flight (TOF) acquired by transmitting and receiving inspection waves such as electromagnetic waves, laser light, and ultrasonic waves. In addition, in FIG. 1, the first sensor 21 and the second sensor 22 are illustrated as independent devices. Alternatively, the first sensor 21 and the second sensor 22 may be integrally configured.

The control device 25 is a device that controls the driving device 15, and may be implemented by a computer including a processor, a memory, and the like. The control device 25 according to the present embodiment estimates a warpage of the substrate 10 held by the spin chuck 11 based on the measurement results of the first sensor 21 and the second sensor 22 and controls the driving device 15 based on the estimation result. In other words, the control device 25 performs a process of optimizing a discharge position of a liquid by the discharge nozzle 14 according to the warpage of the substrate 10. In addition, the control device 25 may control not only the driving device 15 but also the spin chuck 11, the motor 12, the discharge nozzle 14, and the like.

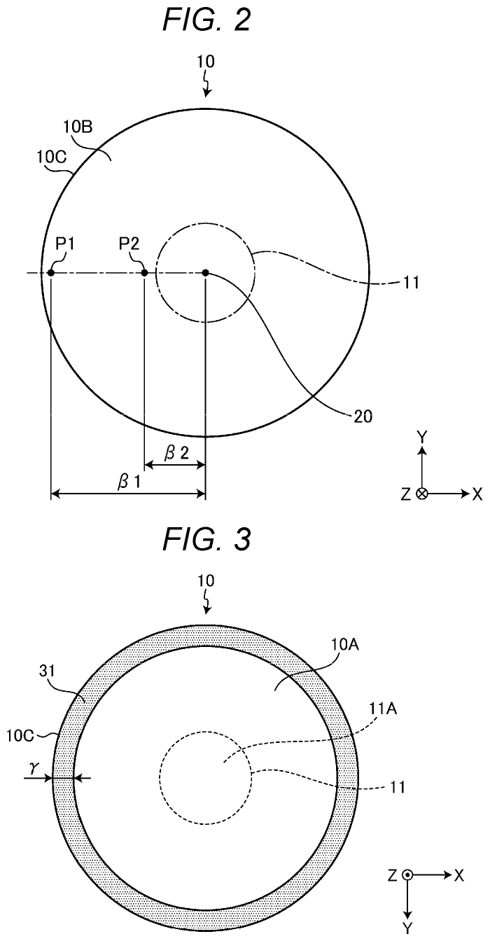

FIG. 2 is a bottom view of the substrate 10 illustrating examples of the first position P1 and the second position P2 according to the embodiment. As illustrated in FIG. 2, the first position P1 according to the present embodiment is set near an outer edge end 10C on the rear surface 10B of the substrate 10, and the second position P2 according to the present embodiment is set near an end portion of the spin chuck 11 on the rear surface 10B of the substrate 10. A distance β1 from a center 20 of the spin chuck 11 or the substrate 10 to the first position P1 is preferably 145 mm to 148 mm (inclusive). In addition, a distance β2 from the center 20 to the second position P2 is preferably 70 mm to 93 mm (inclusive). By setting the distances β1 and β2 as described above, the warpage of the substrate 10 having a diameter of about 300 mm can be correctly estimated, and the discharge position of the liquid can be highly precisely adjusted.

The semiconductor manufacturing device 1 according to the present embodiment performs a process of coating a predetermined process area set on the front surface 10A of the substrate 10 with the liquid.

FIG. 3 is a top view of the substrate 10 illustrating an example of a process area 31 according to the embodiment. As illustrated in FIG. 3, the process area 31 according to the present embodiment may be an inner area from the outer edge end 10C of the front surface 10A of the substrate 10 by a predetermined process width γ. Hereinafter, a process with respect to the process area 31 set along the outer edge end 10C in this manner is referred to as an outer edge process. The outer edge process may be a film forming process of forming a predetermined film in the process area 31 and a peeling process of removing a film formed in the process area 31.

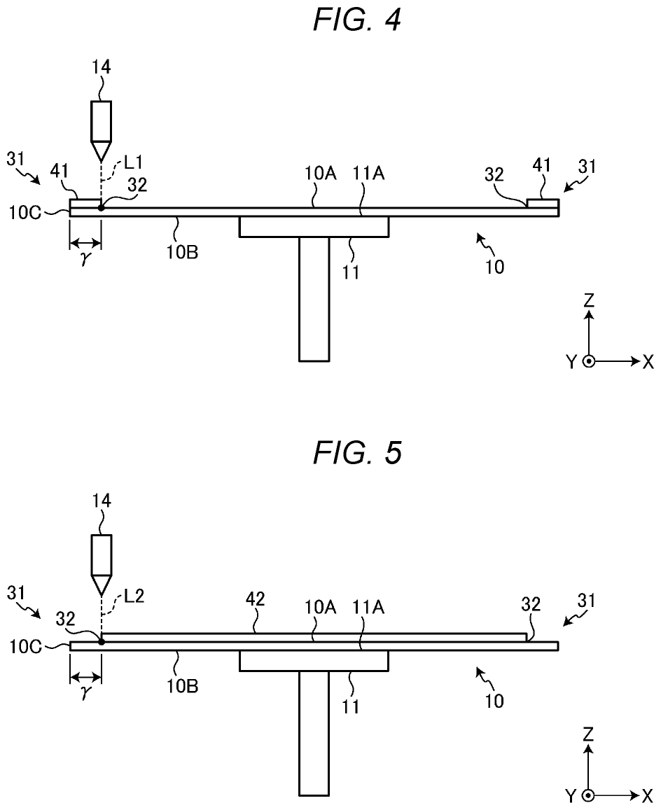

FIG. 4 is a side view illustrating an example of a state in the film forming process according to the embodiment. As illustrated in FIG. 4, when the film forming process is performed on the process area 31, first, a liquid L1 including a resist or the like is discharged to an end portion inside the process area 31, that is, a reference discharge position 32 that is an inner position from the outer edge end 10C by the process width γ, in a state in which the substrate 10 is stopped. Thereafter, by rotating the substrate 10, the liquid L1 discharged to the reference discharge position 32 flows to an outer peripheral side by the centrifugal force to form a layer of the liquid L1 in the process area 31.

FIG. 5 is a side view illustrating an example of a state in the peeling process according to the embodiment. As illustrated in FIG. 5, when the peeling process is performed on the process area 31, first, a liquid L2 including a thinner or the like is discharged to the end portion inside the process area 31, that is, the reference discharge position 32 that is the inner position from the outer edge end 10C by the process width γ, in a state in which the substrate 10 is stopped. Thereafter, by rotating the substrate 10, the liquid L2 discharged to the reference discharge position 32 flows to the outer peripheral side by the centrifugal force, a layer of the liquid L2 is formed in the process area 31, and a layer 42 formed in advance is removed.

When the outer edge process as described above is performed on the substrate 10 without warpage, the liquids L1 and L2 may be discharged to the reference discharge position 32 corresponding to the process width γ. Whereas, when the substrate 10 is warped, the discharge positions of the liquids L1 and L2 are required to be corrected. The control device 25 according to the present embodiment has a function of correcting the discharge position according to the warpage of the substrate 10.

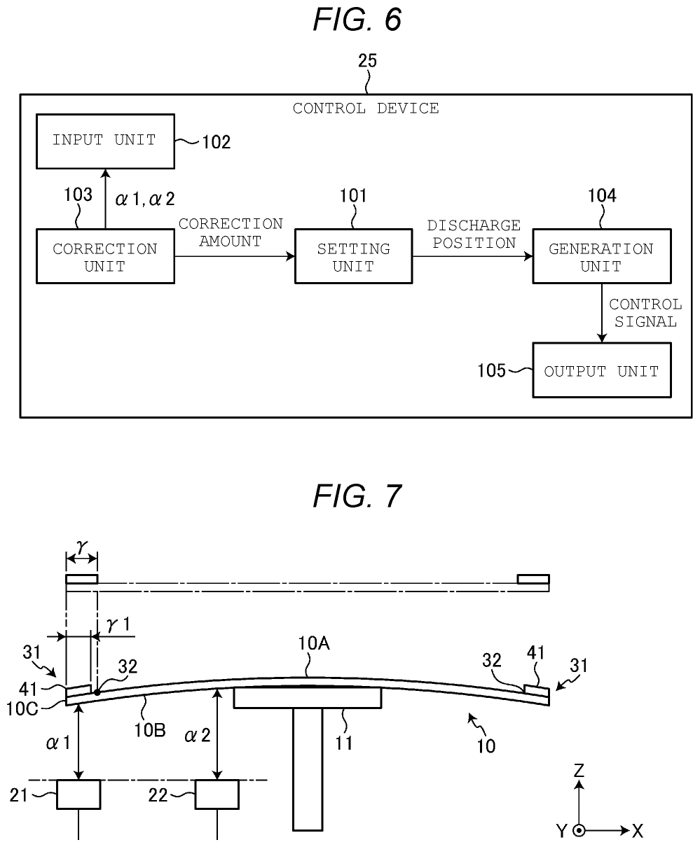

FIG. 6 is a block diagram illustrating an example of a functional configuration of the control device 25 according to the embodiment. The control device 25 according to the present embodiment includes a setting unit 101, an input unit 102, a correction unit 103, a generation unit 104, and an output unit 105. These functional elements 101 to 105 may be implemented by cooperation of hardware elements (e.g., a processor and a memory) and software elements (e.g., a program and firmware) that configure the control device 25. At least a portion of these functional elements 101 to 105 may be embodied by dedicated hardware (e.g., a circuit).

The setting unit 101 sets the reference discharge position 32 on the front surface 10A of the substrate 10. The reference discharge position 32 is a discharge position in a state in which the substrate 10 is not warped, that is, when there is no error between the first distance α1 and the second distance α2 (e.g., including a case where an error is a threshold value or lower). The setting unit 101 sets the reference discharge position 32, for example, based on the process width γ of the process area 31 described above.

After the substrate 10 to be processed is held by the spin chuck 11, the input unit 102 inputs the first distance α1 and the second distance α2 that are measured by the first sensor 21 and the second sensor 22.

The correction unit 103 calculates a correction amount of the discharge position based on the first distance α1 and the second distance α2. When a difference value obtained by subtracting the second distance α2 from the first distance α1 is a negative value, that is, when the substrate 10 is warped in a convex shape so that a central portion of the substrate 10 is positioned above an outer peripheral portion, the correction unit 103 according to the present embodiment calculates the correction amount so that the corrected discharge position is on the inner side of the substrate 10 from the reference discharge position 32. In addition, when the difference value is a positive value, that is, when the substrate 10 is warped in a concave shape so that the central portion of the substrate 10 is positioned below the outer peripheral portion, the correction unit 103 calculates the correction amount so that the corrected discharge position is on an outer side of the substrate 10 from the reference discharge position 32.

The generation unit 104 generates a control signal for controlling the driving device 15 based on the corrected discharge position. In addition, the corrected discharge position becomes a discharge position obtained by correcting the reference discharge position 32 with the correction amount when the substrate 10 is warped, and the corrected discharge position becomes the reference discharge position 32 when the substrate 10 is not warped.

The output unit 105 outputs the control signal generated by the generation unit 104 to the driving device 15.

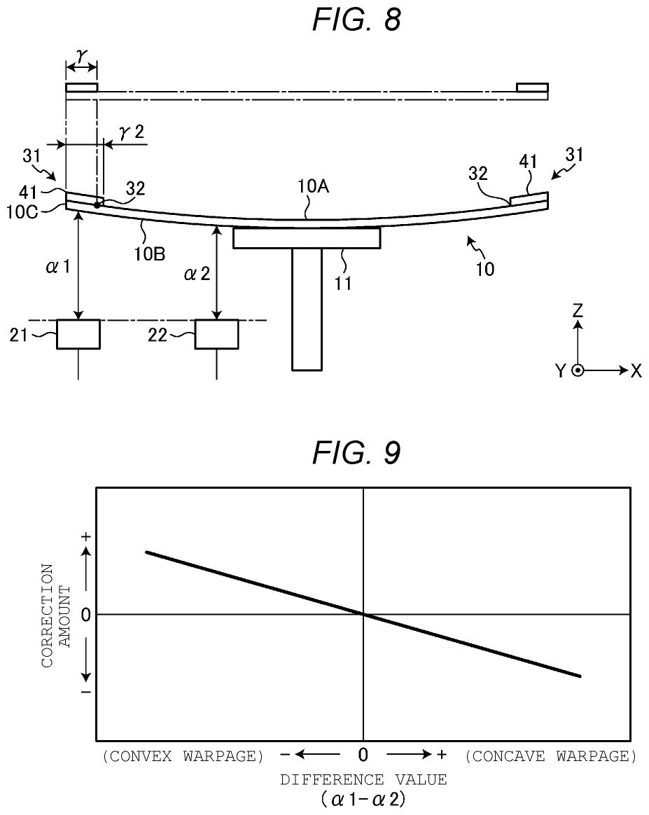

FIG. 7 is a side view illustrating an example of a state when the substrate 10 is warped in the convex shape in the embodiment. FIG. 8 is a side view illustrating an example of a state when the substrate 10 is warped in the concave shape in the embodiment. Here, a case where a film forming process of forming a resist film 41 in the process area 31 is described as an example.

As illustrated in FIG. 7, when the substrate 10 is warped in the convex shape, the first distance α1 becomes smaller than the second distance α2, and thus the difference value obtained by subtracting the second distance α2 from the first distance α1 becomes a negative value. In such a case, when the liquid L1 to be a raw material of the resist film 41 is discharged to the reference discharge position 32, a final process width γ1 of the resist film 41 becomes smaller than a target process width γ due to an influence of an inclination of the substrate 10.

On the other hand, as illustrated in FIG. 8, when the substrate 10 is warped in the concave shape, the first distance α1 becomes larger than the second distance α2, and the difference value obtained by subtracting the second distance α2 from the first distance α1 becomes a positive value. In such a case, when the liquid L1 is discharged to the reference discharge position 32, a final process width γ2 of the resist film 41 becomes larger than the target process width γ by the influence of the inclination of the substrate 10.

A deviation of the process width caused by the warpage of the substrate 10 as described above occurs in the same manner when the peeling process is performed on the process area 31.

The correction unit 103 according to the present embodiment calculates the correction amount for correcting the discharge position of the liquid so that the deviation of the process width as described above (i.e., an error between γ and γ1 or an error between γ and γ2) becomes small. The correction amount may be calculated with an appropriate method. For example, the correction amount may be calculated using a correction table showing a relationship between a parameter corresponding to a warpage amount of the substrate 10 and the correction amount. In addition, the warpage amount is a value indicating a degree of the warpage of the substrate 10. For example, the warpage amount may be a height difference between the center of one surface of the substrate 10 (i.e., the front surface 10A or the rear surface 10B) and the outer edge end 10C of the corresponding one surface.

FIG. 9 is a diagram illustrating an example of a correction table according to the embodiment. Here, the correction table described as an example shows a relationship between the difference value obtained by subtracting the second distance α2 from the first distance α1 and the correction amount of the discharge position. The difference value is an example of the parameter corresponding to the warpage amount of the substrate 10. When the difference value is a positive value, the substrate 10 is warped in the concave shape, and when the difference value is a negative value, the substrate 10 is warped in the convex shape. When the correction value is a positive value, the discharge position is corrected to the inner side of the substrate 10 from the reference discharge position 32, and when the correction value is a negative value, the discharge position is corrected to the outer side of the substrate 10 from the reference discharge position 32. The corresponding correction table shows that, the larger the warpage amount of the substrate 10 toward the convex side, the larger the correction amount of the discharge position toward the inner side, and the larger the warpage amount of the substrate 10 toward the concave side, the larger the correction amount of the discharge position toward the outer side.

In addition, the correction table illustrated in FIG. 9 is merely an example, and a configuration of the correction table is not limited to the above description. For example, the correction table may be configured so that the correction amount can be individually specified according to the type of liquid used, the type of process to be performed (e.g., whether the process is the film forming process or the peeling process), and the like.

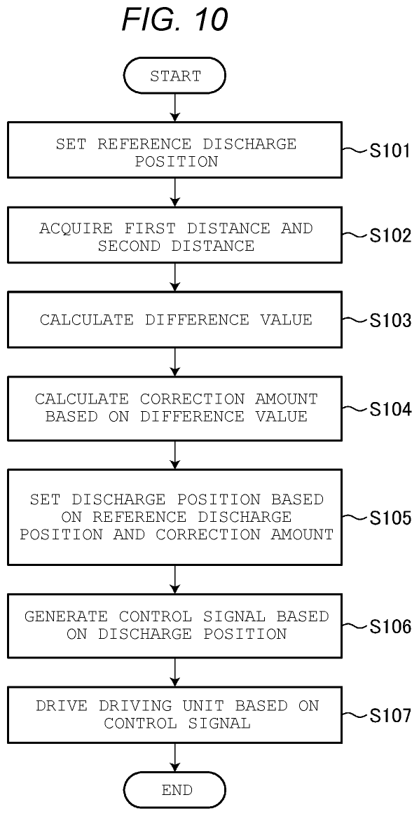

FIG. 10 is a flowchart illustrating an example of a process when the driving device 15 is controlled in the semiconductor manufacturing device 1 according to the embodiment. When the substrate 10 to be processed is held by the spin chuck 11, the setting unit 101 sets the reference discharge position 32 based on the predetermined process width γ of the process area 31 or the like (S101). The input unit 102 acquires the first distance α1 and the second distance α2 measured by the first sensor 21 and the second sensor 22 (S102). The correction unit 103 calculates the difference value obtained by subtracting the second distance α2 from the first distance α1 (S103) and calculates the correction amount of the discharge position based on the corresponding difference value (S104). The corresponding correction amount is calculated, for example, by using the correction table as illustrated in FIG. 9 so that an influence by the warpage of the substrate 10 is decreased.

Thereafter, the setting unit 101 sets the corrected discharge position based on the reference discharge position 32 and the calculated correction amount (S105). The generation unit 104 generates the control signal for controlling the driving device 15 based on the corrected discharge position (S106). The driving device 15 is driven based on the corresponding control signal (S107) and displaces the discharge nozzle 14 so that the liquid is discharged to the corrected discharge position.

The discharge position of the liquid according to the warpage of the substrate 10 can be optimized by the process described above. Accordingly, even when the substrate 10 is warped, the process can be highly precisely performed by the spin coat method.

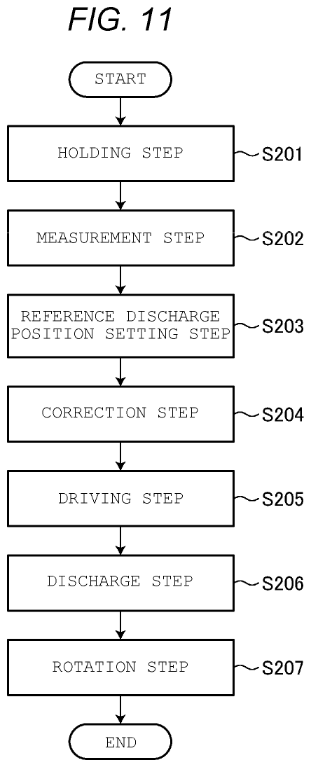

FIG. 11 is a flowchart illustrating an example of a process of a method for manufacturing a semiconductor device using the semiconductor manufacturing device 1 according to the embodiment. First, a holding step of holding the substrate 10 to be processed is performed on the spin chuck 11 (S201). Thereafter, a measurement step of measuring the first distance α1 and the second distance α2 by the first sensor 21 and the second sensor 22 is performed (S202). Thereafter, the reference discharge position setting step of setting the reference discharge position 32 corresponding to the case where the substrate 10 is not warped is performed (S203). In addition, the reference discharge position setting step (S203) may be performed before the measurement step (S202).

Thereafter, a correction step of correcting the discharge position based on the first distance α1 and the second distance α2 is performed (S204). For example, the corresponding correction step may be performed by calculating the correction amount from the reference discharge position 32 based on the difference value obtained by subtracting the second distance α2 from the first distance α1 and setting the corrected discharge position based on the corresponding correction amount as described above. Thereafter, a driving step of displacing the discharge nozzle 14 based on the corrected discharge position is performed (S205). Thereafter, a discharge step of discharging the liquid to the corrected discharge position from the discharge nozzle 14 is performed (S206). Thereafter, a rotation step of rotating the substrate 10 held by the spin chuck 11 is performed (S207). Accordingly, the liquid discharged to the corrected discharge position flows in an outer peripheral direction due to the centrifugal force, and enters a state in which the predetermined process area 31 is coated with the liquid. In addition, thereafter, a step of drying the coated liquid, a step of curing the coated liquid by irradiation with ultraviolet rays, a step of washing the process area 31 or the like may be performed.

According to the manufacturing method as described above, even when the substrate 10 is warped, a highly precise front surface process can be performed on the substrate 10, and thus a high-quality semiconductor device can be manufactured.

In order to embody the functions as described above, programs for causing the computer that configure the control device 25 and the like to perform predetermined processes may be provided by being recorded in a computer-readable recording medium such as CD-ROM, a flexible disk (FD), CD-R, or a digital versatile disk (DVD) as files in a format that may be installed in or executed by the computer. Further, the corresponding programs may be configured to be provided by being stored on a computer connected to a network such as the Internet and downloaded via the network. Further, the corresponding programs may be configured to be provided or distributed via the network such as the Internet.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor manufacturing device comprising:
a holder that holds a substrate and rotates;
a discharger that discharges a liquid to a front surface of the substrate held by the holder;
a driver that displaces the discharger;
a controller that controls the driver such that the liquid is discharged to a discharge position of the front surface;
a first sensor that measures a first distance from a reference surface below a rear surface of the substrate held by the holder to a first position of the rear surface;
a second sensor that measures a second distance from the reference surface to a second position of the rear surface, the second point being on an inner side from the first position of the rear surface; and
a processor that corrects the discharge position based on the first distance and the second distance.

2. The semiconductor manufacturing device according to claim 1, wherein the processor is configured to:
determine whether a difference value obtained by subtracting the second distance from the first distance is a negative value or a positive value;
responsive to determining that the difference value is a negative value, correct the discharge position to be on an inner side from a reference discharge position which is a discharge position when the difference value is 0; and
responsive to determining that the difference value is a positive value, correct the discharge position to be on an outer side from the reference discharge position.

3. The semiconductor manufacturing device according to claim 1,
wherein the discharger is configured to discharge, using the corrected discharge position, a liquid to a process area which is an inner area from an outer edge end of the substrate by a predetermined process width.

4. The semiconductor manufacturing device according to claim 3,
wherein the discharger is configured to discharge the liquid using the corrected discharge position to form a predetermined film in the process area.

5. The semiconductor manufacturing device according to claim 4,
wherein the liquid includes a resist.

6. The semiconductor manufacturing device according to claim 3,
wherein the discharger is configured to discharge the liquid using the corrected discharge position to remove a film formed in the process area.

7. The semiconductor manufacturing device according to claim 6,
wherein the liquid includes a thinner.

8. The semiconductor manufacturing device according to claim 1,
wherein the first position is within an inclusive range of 145 mm to 148 mm from a center of the holder.

9. The semiconductor manufacturing device according to claim 1,
wherein the second position is within an inclusive range of 70 mm to 93 mm from a center of the holder.

10. The semiconductor manufacturing device according to claim 1, wherein
the processor is configured to generate a control signal for controlling the driver based on the corrected discharge position, and
the driver is configured to displace the discharger based on the control signal.

11. A method for manufacturing a semiconductor device, comprising:
holding a substrate to be processed by a holder that holds the substrate and rotates;
measuring a first distance from a reference surface below a rear surface of the substrate held by the holder to a first position of the rear surface and a second distance from the reference surface to a second position of the rear surface, the second position being on an inner side from the first position of the rear surface;
setting a discharge position at which a liquid is discharged to a front surface of the substrate held by the holder;
correcting the discharge position based on the first distance and the second distance;
displacing a discharger that discharges the liquid based on the corrected discharge position;
discharging the liquid to the corrected discharge position; and
rotating the substrate held by the holder after the liquid is discharged.

12. The method according to claim 11, wherein correcting the discharge position comprises:
determining whether a difference value obtained by subtracting the second distance from the first distance is a negative value or a positive value;
responsive to determining that the difference value is a negative value, correcting the discharge position to be on an inner side from a reference discharge position which is a discharge position when the difference value is 0; and
responsive to determining that the difference value is a positive value, correcting the discharge position to be on an outer side from the reference discharge position.

13. The method according to claim 11,
wherein discharging the liquid to the corrected discharge position comprises:
discharging, using the corrected discharge position, a liquid to a process area which is an inner area from an outer edge end of the substrate by a predetermined process width.

14. The method according to claim 13,
wherein the liquid is discharged using the corrected discharge position to form a predetermined film in the process area.

15. The method according to claim 14,
wherein the liquid includes a resist.

16. The method according to claim 13,
wherein the liquid is discharged using the corrected discharge position to remove a film formed in the process area.

17. The method according to claim 16,
wherein the liquid includes a thinner.

18. The method according to claim 11,
wherein the first position is within an inclusive range of 145 mm to 148 mm from a center of the holder.

19. The method according to claim 11,
wherein the second position is within an inclusive range of 70 mm to 93 mm from a center of the holder.

20. The method according to claim 11, further comprising:
generating a control signal for controlling, based on the corrected discharge position, a driver that displaces the discharger, and
displacing, by the driver, the discharger based on the control signal.
